(19) United States
(12) Patent Application Publication
(10) Pub. No.: US 2026/0173753 A1
(43) Pub. Date: Jun. 18, 2026

(54) THIN-FILM LIGHT-EMITTING DEVICE AND DISPLAY PANEL

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Guangru LI, Beijing (CN); Xiaofei ZHAO, Beijing (CN); Yang GAO, Beijing (CN)

(21) Appl. No.: 19/506,202

(22) PCT Filed: Mar. 26, 2024
(86) PCT No.: PCT/CN2024/083746

§ 371 Date: Jan. 28, 2026

(30) Foreign Application Priority Data
Aug. 1, 2023 (CN) 202310957423.1

(51) Int. Cl. H10K 85/60; H10K 50/11

(52) U.S. Cl. CPC H10K 85/6572; H10K 50/11; H10K 85/633

(57) ABSTRACT

The present disclosure relates to the technical field of display, and provides a thin-film light-emitting device and a display panel. The thin-film light-emitting device includes an anode, a hole transport layer, a light-emitting layer, and a cathode which are sequentially stacked. The hole transport layer includes a hole transport material and a triplet quenching material, and the triplet quenching material can quench at least some of triplet excitons in the hole transport material.

### CROSS REFERENCE

The present disclosure claims priority to Chinese Patent Application No. 202310957423.1, filed on Aug. 1, 2023 and entitled “THIN-FILM LIGHT-EMITTING DEVICE, PREPARATION METHOD THEREOF, AND DISPLAY PANEL”, and the entire content thereof is incorporated herein by reference.

### TECHNICAL FIELD

The present disclosure relates to the field of display technology, and in particular, to a thin-film light-emitting device and a display panel.

### BACKGROUND

Quantum-dot light-emitting diodes are a luminescent display technology that has been very close to commercialization in recent years. The hole transport layer of the quantum-dot light-emitting diode generally uses organic semiconductor materials, but these organic semiconductor materials are easily damaged, which leads to a decrease in the performance of the quantum-dot light-emitting diode.

It should be noted that the information disclosed in above section is only for enhancement of understanding of the background of the present disclosure, and therefore may contain information that does not form the prior art already known to a person of ordinary skill in the art.

### SUMMARY

The purpose of the present disclosure is to overcome above-mentioned shortcomings of the prior art, and to provide a thin-film light-emitting device, a preparation method for the thin-film light-emitting device, and a display panel, to improve the stability of the hole transport layer.

According to one aspect of the present disclosure, a thin-film light-emitting device is provided, including an anode, a hole transport layer, a light-emitting layer, and a cathode stacked in sequence;
wherein the hole transport layer includes a hole transport material and a triplet quenching material, and the triplet quenching material is capable of quenching at least a portion of triplet excitons in the hole transport material;
wherein the triplet quenching material includes a linking group and at least one quenching group attached to the linking group, and a structure of the quenching group is selected from structures:

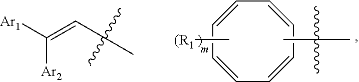

where Ar₁ and Ar₂ are independently selected from substituted or unsubstituted aryl with 6-30 carbon atoms, and substituted or unsubstituted heteroaryl with 4-30 carbon atoms;
R₁ is selected from deuterium, alkyloxycarbonyl with 1-18 carbon atoms, alkylcarbonyl with 1-18 carbon atoms, alkoxyl with 1-18 carbon atoms, alkyl with 1-18 carbon atoms, cycloalkoxycarbonyl with 5-10 carbon atoms, cycloalkylcarbonyl with 5-10 carbon atoms, cycloalkoxyl with 5-10 carbon atoms, cycloalkyl with 5-10 carbon atoms, substituted or unsubstituted aryl with 6-18 carbon atoms, and substituted or unsubstituted heteroaryl with 4-18 carbon atoms;
m is a positive integer selected from 0-7.

According to embodiments of the present disclosure, a number of the quenching group of the triplet quenching material is 2-4.

According to embodiments of the present disclosure, the quenching group of the triplet quenching material is selected from

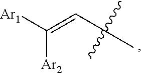

the linking group of the triplet quenching material has an aromatic structure, and the quenching group is directly attached to the aromatic structure.

According to embodiments of the present disclosure, Arᵢ and Ar₂ are independently selected from substituted or unsubstituted phenyl, substituted or unsubstituted naphthyl, and substituted or unsubstituted biphenyl;
in the case that Ar₁ or Ar₂ has a substituent, any substituent is selected from deuterium, methyl, ethyl, and isopropyl.

According to embodiments of the present disclosure, the linking group is selected from substituted or unsubstituted biphenyl, substituted or unsubstituted spirofluorenyl, substituted or unsubstituted triphenyl, substituted or unsubstituted naphthyl, substituted or unsubstituted anthracene, substituted or unsubstituted phenanthrene, and substituted or unsubstituted phenyl;
in the case that the linking group has a substituent, any substituent is independently selected from deuterium, methyl, ethyl, and isopropyl.

According to embodiments of the present disclosure, the triplet quenching material is selected from 4,4′-Bis(2,2-diphenylethenyl)-1,1′-biphenyl and 2,2,7,7′-Tetrakis(2,2-diphenylethenyl)-9,9′-spirobifluorene.

According to embodiments of the present disclosure, the quenching group of the triplet quenching material is selected from

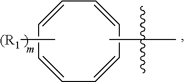

and a molecular weight of the triplet quenching material is between 600 and 1200.

According to embodiments of the present disclosure, the linking group has an organic semiconductor structure with a hole transport property, or the linking group is a flexible linking group with at least two flexible arms, and any one of the flexible arms is attached to one of the quenching group.

According to embodiments of the present disclosure, a HOMO energy level of the triplet quenching material is not higher than the HOMO energy level of the hole transport material.

According to embodiments of the present disclosure, a difference between a LUMO energy level of the triplet quenching material and the LUMO energy level of the hole transport material is not lower than −1 eV

According to embodiments of the present disclosure, the LUMO energy level of the triplet quenching material is not lower than the LUMO energy level of the hole transport material.

According to embodiments of the present disclosure, a hole mobility of the triplet quenching material is less than the hole mobility of the hole transport material.

According to embodiments of the present disclosure, a triplet energy level of the triplet quenching material is lower than the triplet energy level of the hole transport material.

According to embodiments of the present disclosure, a singlet energy level of the triplet quenching material is higher than the singlet energy level of the hole transport material.

According to embodiments of the present disclosure, a mass ratio of the triplet quenching material in the hole transport layer is between 0.0001% and 90%.

According to embodiments of the present disclosure, the mass ratio of the triplet quenching material in the hole transport layer is between 1% and 30%.

According to embodiments of the present disclosure, the mass ratio of the triplet quenching material in the hole transport layer is between 2% and 10%.

According to embodiments of the present disclosure, the hole transport material is an organic semiconductor material, and the light-emitting layer is a quantum dot luminescent layer.

According to embodiments of the present disclosure, the thin-film light-emitting device is a blue thin-film light-emitting device.

According to another aspect of the present disclosure, a display panel is provided, including the thin-film light-emitting device as described above.

It should be understood that the foregoing general description and the following detailed description are exemplary and explanatory only and are not restrictive of the present disclosure.

### BRIEF DESCRIPTION OF THE DRAWINGS

The drawings, which are incorporated in and constitute a part of this specification, illustrate embodiments consistent with the present disclosure and serve together with the specification to explain the principles of the present disclosure. It is apparent that the drawings in the following description are only some embodiments of the present disclosure, and for those of ordinary skill in the art, other drawings can also be obtained from these drawings without creative efforts.

FIG. 1 is a schematic diagram of a structure of a thin-film light-emitting device according to one or more embodiments.

FIG. 2 is a schematic diagram of a structure of a thin-film light-emitting device according to one or more embodiments.

FIG. 3 is a schematic diagram of a structure of a thin-film light-emitting device according to one or more embodiments.

FIG. 4 is a schematic diagram of a structure of a thin-film light-emitting device according to one or more embodiments.

FIG. 5 is a schematic diagram of a structure of a thin-film light-emitting device according to one or more embodiments.

FIG. 6 shows luminescence intensity curves of each thin film according to a first verification example.

FIG. 7 shows luminescence intensity curves of each thin film according to a second verification example.

FIG. 8 shows current vs. voltage curves and luminance vs. voltage curves of Test Device A, Test Device B, and Test Device C.

FIG. 9 shows current efficiency vs. voltage curves and external quantum efficiency (EQE) vs. voltage curves of Test Device A, Test Device B, and Test Device C.

FIG. 10 shows life test results and voltage test results of Test Device A and Test Device B.

FIG. 11 shows current vs. voltage curves and luminance vs. voltage curves of Test Device D, Test Device E, Test Device F, and Test Device G.

FIG. 12 shows current efficiency vs. voltage curves and external quantum efficiency (EQE) vs. voltage curves of Test Device D, Test Device E, Test Device F, and Test Device G.

FIG. 13 shows life test results and voltage test results of Test Device D, Test Device E, Test Device F, and Test Device G.

### DETAILED DESCRIPTION

Example embodiments will now be described more comprehensively with reference to the drawings. However, the example embodiments can be implemented in various ways and should not be construed as limited to the embodiments set forth herein. Instead, these embodiments are provided so that the present disclosure will be thorough and complete, and will fully convey the concept of example embodiments to those skilled in the art. The same reference signs in the drawings denote the same or similar structures, and thus their detailed descriptions will be omitted. Furthermore, the drawings are merely schematic illustrations of the present disclosure and are not necessarily drawn to scale.

The description adopted in the present disclosure “ . . . each independently selected from” should be broadly understood, which can mean that specific options expressed by the same symbols in different groups do not affect each other, or specific options expressed by the same symbols in the same group do not affect each other. For example,

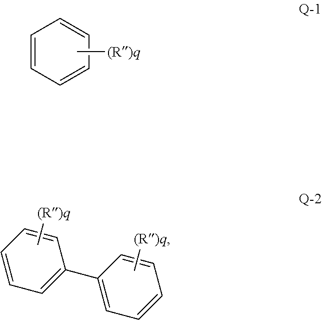

in which, each “q” is independently 0, 1, 2, or 3, and each “R″” is independently selected from hydrogen, deuterium, fluorine, and chlorine. The meaning is that formula Q-1 represents that there are q substituents R″ on the benzene ring, and each R″ can be the same or different, that is, options for each R″ do not affect each other. Formula Q-2 represents that each benzene ring of the biphenyl has q substituents R″, and the number q of the substituents R″ on two benzene rings can be the same or different, and each R″ can be the same or different, that is, options for each R″ do not affect each other.

A non-locating bond in the present disclosure refers to a single bond [symbol] extending outward from a ring system, meaning that one end of the bond can be attached to any position in the ring system it passes through, and the other end can be attached to the remainder of the compound molecule.

For example, as shown in following formula (f), the naphthyl represented by formula (f) is attached to other positions of the molecule through two non-locating bonds that pass through the bicyclic rings, which means that any possible attachment way as shown in formulas (f-1) to (f-10) are included.

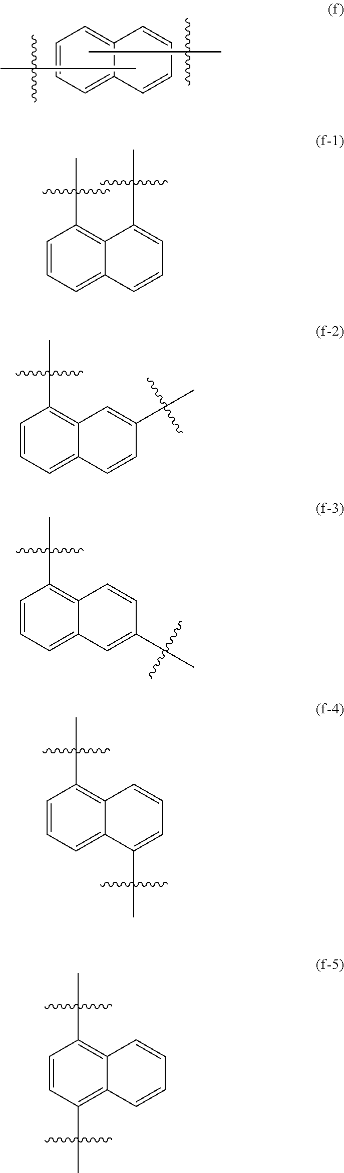

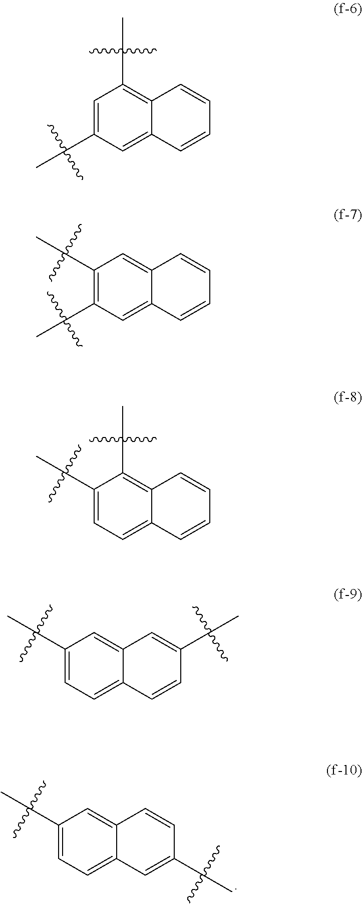 [SMILES: *c1cc(*)c2ccccc2c1 ; *c1cc2ccccc2cc1* ; *c1ccc2ccccc2c1* ; *c1ccc2ccc(*)cc2c1 ; *c1ccc2cc(*)ccc2c1]

For example, as shown in the following formula (X′), the phenanthryl represented by formula (X′) is attached to other positions of the molecule through one non-locating bond extending outward from the middle of the benzene ring on a side, which means that any possible attachment way as shown in formulas (X′-1) to (X′-4) are included.

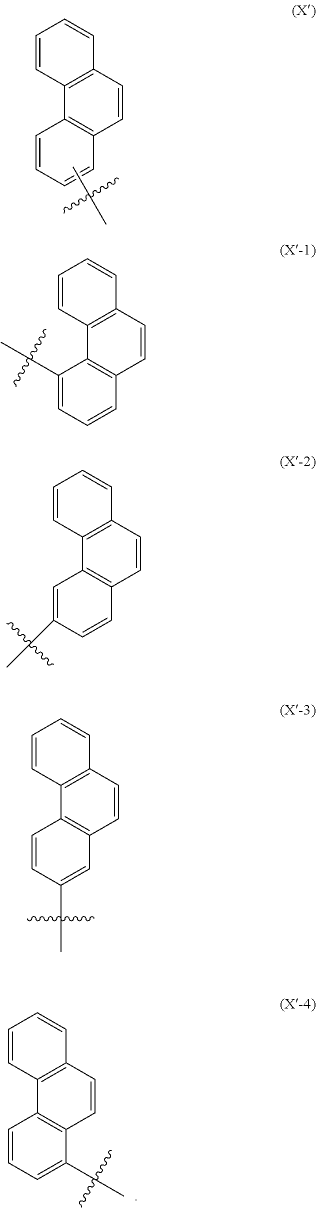

The non-directing substituent in the present disclosure refers to a substituent attached through a single bond extending outward from the center of the ring system, meaning that the substituent can be attached to any possible position in the ring system. For example, as shown in following formula (Y), the substituent R′ represented by formula (Y) is attached to the quinoline ring through one non-locating bond, which means that any possible attachment way as shown in formulas (Y-1) to (Y-7) are included.

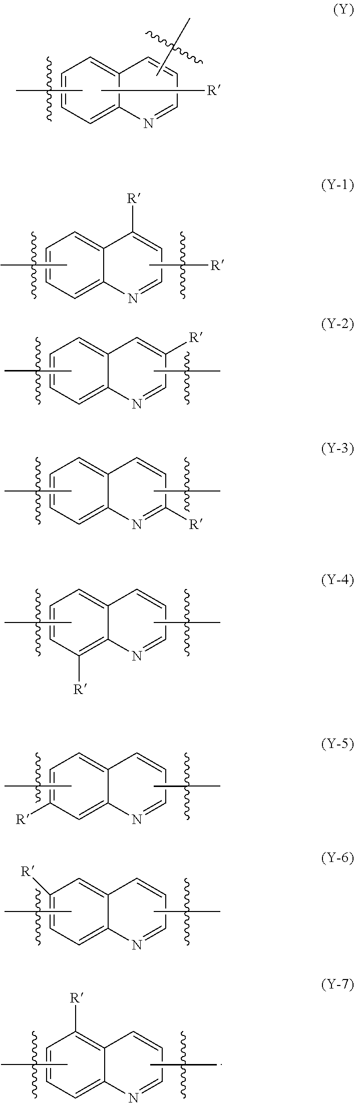

In the present disclosure, for substituted or unsubstituted aryl with M carbon atoms, or substituted or unsubstituted heteroaryl with M carbon atoms, the number of carbon atoms M is calculated without considering the number of carbons on the substituent, but only considering the number of carbons on an aryl or heteroaromatic ring. For example,

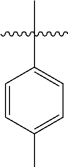 [SMILES: *c1ccc(C)cc1]

is a methyl substituted aryl with 6 carbon atoms, and

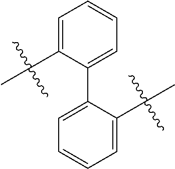 [SMILES: *c1ccccc1-c1ccccc1*]

is an unsubstituted heteroaryl with 12 carbon atoms.

In the present disclosure, unless otherwise specifically defined, “hetero” refers to the inclusion of at least one heteroatom such as B, N, O, S, Se, Si, P, etc. in a functional group, with other atoms being carbon, hydrogen, and deuterium. The unsubstituted alkyl group can be a “saturated alkyl group” without any double or triple bond.

In the present disclosure, the “alkyl group” can include a linear or branched alkyl group. The alkyl group can contain 1 to 18 carbon atoms. In the present disclosure, the numerical range such as “1 to 18” refers to each integer within the given range. For example, “an alkyl group with 1 to 18 carbon atoms” refers to the alkyl that can contain 1 carbon atom, 2 carbon atoms, 3 carbon atoms, 4 carbon atoms, 5 carbon atoms, 6 carbon atoms, 7 carbon atoms, 8 carbon atoms, 9 carbon atoms, 10 carbon atoms, 11 carbon atoms, 12 carbon atoms, 13 carbon atoms, 14 carbon atoms, 15 carbon atoms, 16 carbon atoms, 17 carbon atoms, or 18 carbon atoms. In some embodiments, the alkyl group can also be a small alkyl group with 1 to 5 carbon atoms.

In some embodiments, the alkyl group is selected from an alkyl group with 1 to 5 carbon atoms, and specific embodiments include, but are not limited to, methyl, ethyl, n-propyl, isopropyl, n-butyl, isobutyl, sec-butyl, tert-butyl, and pentyl.

In the present disclosure, the cycloalkyl group refers to a group derived from a saturated cyclic carbon chain structure. The cycloalkyl group can contain 5 to 10 carbon atoms. In the present disclosure, the numerical range such as “a cycloalkyl group with 5 to 10 carbon atoms” refer to each integer within the given range. For example, “a cycloalkyl group with 5 to 10 carbon atoms” refers to the cycloalkyl group that can contain 5 carbon atoms, 6 carbon atoms, 7 carbon atoms, 8 carbon atoms, 9 carbon atoms, or 10 carbon atoms.

In some embodiments, specific embodiments of the cycloalkyl group include, but are not limited to, cyclopentyl, cyclohexyl, adamantyl, norbornyl, etc.

In the present disclosure, the aryl group refers to any optional functional group or substituent derived from an aromatic carbocycle, which can be a monocyclic aryl group (such as phenyl) or a polycyclic aryl group. In other words, the aryl group can be a monocyclic aryl group, a fused aryl group, two or more monocyclic aryl groups linked through a carbon-carbon bond in a conjugate manner, a monocyclic aryl group and a fused aryl group linked through a carbon-carbon bond in a conjugate manner, or two or more fused aryl groups linked through a carbon-carbon bond in a conjugate manner. That is, unless otherwise specified, two or more aryl groups linked through a carbon-carbon bond in a conjugate manner can also be considered as the aryl group in the present disclosure. The fused aryl group can include, for example, a bicyclic fused aryl group (such as naphthyl), a tricyclic fused aryl group (such as phenanthryl, fluorenyl, anthracenyl), etc. The aryl group does not contain heteroatoms such as B, N, O, S, P, Se, Si, etc. For example, in the present disclosure, the biphenyl, the terphenyl, etc. are considered as the aryl group. Examples of the aryl group can include, but are not limited to, phenyl, naphthyl, fluorenyl, anthryl, phenanthryl, biphenylyl, terphenyl, quaterphenylyl, quinquephenylyl, benzo[9,10]phenanthrenyl, pyrenyl, benzfluoranthenyl, dibenzofuranyl, etc. In the present disclosure, the “biphenylyl group” can be understood as a phenyl-substituted aryl group or as an unsubstituted aryl group. In the present disclosure, the term “arylene group” refers to a divalent group formed by further loss of one hydrogen atom from an aryl group.

In the present disclosure, the substituted aryl group can be one in which one or more hydrogen atoms in the aryl group are substituted by groups such as deuterium atoms, aryl, heteroaryl, alkyl, cycloalkyl, alkoxy, etc.

In the present disclosure, the heteroaryl group refers to a monovalent aromatic ring or its derivatives containing at least one heteroatom in the ring, where the heteroatom can be at least one of B, O, N, P, Si, Se, or S. The heteroaryl group can be either monocyclic or polycyclic. In other words, the heteroaryl group can be an aromatic single-ring system or aromatic multi-ring system linked through a carbon-carbon bond in a conjugate manner, and any aromatic ring system can be an aromatic single ring or an aromatic fused ring. For example, the heteroaryl group can include thienyl, furanyl, pyrrolyl, imidazolyl, thiazolyl, oxazolyl, oxadiazolyl, triazolyl, pyridinyl, bipyridinyl, pyrimidinyl, triazinyl, acridinyl, pyridazinyl, pyrazinyl, quinolinyl, quinazolinyl, quinoxalinyl, phenoxazinyl, phthalazinyl, pyridopyrimidinyl, pyridopyrazinyl, pyrazinopyrazinyl, isoquinolinyl, indolyl, carbazolyl, benzoxazolyl, benzimidazolyl, benzothiazolyl, benzocarbazolyl, benzothienyl, dibenzothienyl, thienothienyl, benzofuranyl, phenanthrolineyl, isoxazolyl, thiadiazolyl, benzothiazolyl, phenothiazinyl, silylfulvenyl, dibenzofuranyl, and N-arylcarbazolyl (such as N-phenylcarbazolyl), N-heteroarylcarbazolyl (such as N-pyridylcarbazolyl), N-alkylcarbazolyl (such as N-methylcarbazolyl), etc., but is not limited to these. The thienyl, furanyl, phenanthrolinyl, etc. are the monocyclic heteroaryl groups, and N-arylcarbazolyl (such as N-phenylcarbazolyl) and N-heteroarylcarbazolyl are the polycyclic heteroaryl groups linked through a carbon-carbon bond in a conjugate manner.

In the present disclosure, the substituted heteroaryl group can be one in which one or more hydrogen atoms in the heteroaryl group are substituted by groups such as deuterium atoms, aryl, heteroaryl, alkyl, cycloalkyl, alkoxy, etc.

In embodiments of the present disclosure, unless otherwise specified, the HOMO and LUMO energy levels of the compound are both measured using the same method. Specifically, the cyclic voltammetry can be employed for this purpose. In some embodiments, the HOMO and LUMO energy levels of the compound can also be determined using the ultraviolet photoelectron spectroscopy (UPS) or other methods.

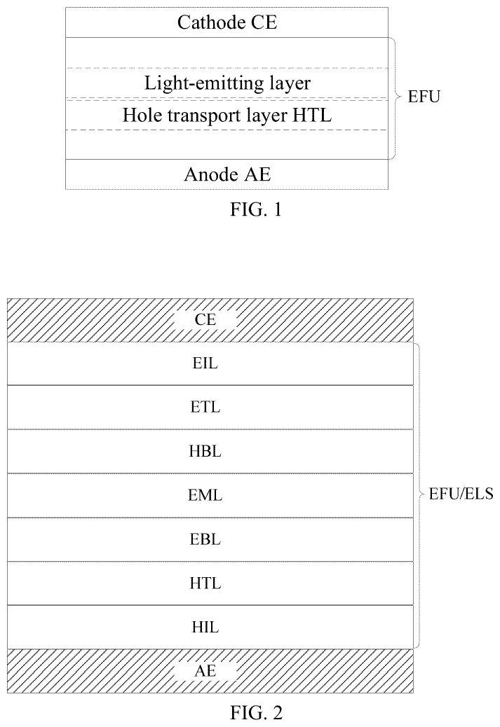

Embodiments of the present disclosure provide a thin-film light-emitting device and a display panel to which the thin-film light-emitting device is applied. As shown in FIG. 1, the thin-film light-emitting device includes an anode AE and a cathode CE arranged in a stacked manner, as well as an emission functional unit EFU sandwiched between the anode AE and the cathode CE. As shown in FIG. 1, the emission functional unit EFU includes at least a hole transport layer HTL and a light-emitting layer. The hole transport layer HTL is located on a side of the light-emitting layer close to the anode AE. The anode and the cathode provide carriers such as electrons and holes to the emission functional unit EFU, respectively, to enable the light-emitting layer of the emission functional unit EFU to emit light. It should be understood that different types of thin-film light-emitting devices may have different materials and film layers for the emission functional unit EFU.

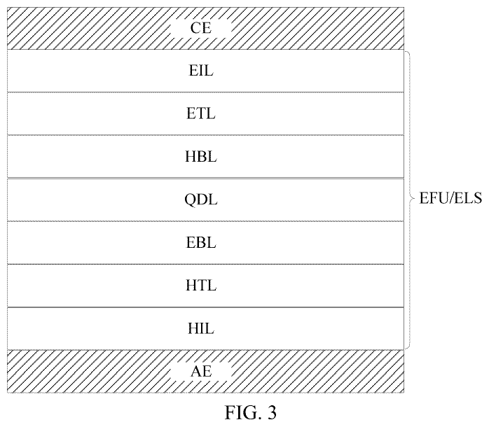

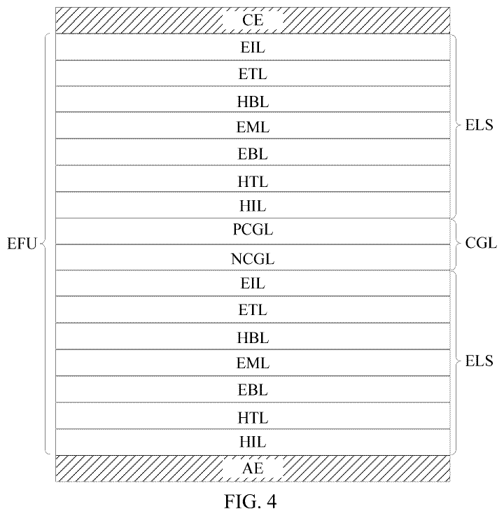

In some embodiments, as shown in FIG. 2, when the thin-film light-emitting device is an OLED (organic light-emitting diode), the emission functional unit EFU can include an organic emission layer EML serving as the light-emitting layer, and can also include one or more of a hole injection layer, a hole transport layer HTL, an electron blocking layer EBL, a hole blocking layer HBL, an electron transport layer ETL, and an electron injection layer EIL, with at least inclusion of the hole transport layer HTL. Further, the organic emission layer EML can include an emission layer host material and an emission layer guest material, where the emission layer guest material can be a fluorescent dopant or a phosphorescent dopant, especially a thermally activated delayed fluorescence material. As shown in FIG. 4, when the OLED adopts a stacked structure, the emission functional unit EFU can also be provided with a charge generation layer CGL.

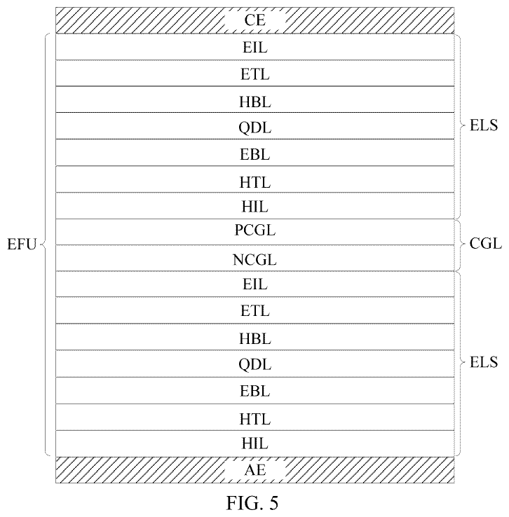

In some embodiments, as shown in FIG. 3, when the thin-film light-emitting device is a QLED (quantum-dot light-emitting diode), the emission functional unit EFU can include a quantum dot luminescent layer QDL serving as the light-emitting layer, and can also include one or more of a hole injection layer, a hole transport layer HTL, an electron blocking layer EBL, a hole blocking layer HBL, an electron transport layer ETL, and an electron injection layer EIL, with at least inclusion of the hole transport layer HTL. The quantum dot luminescent layer can include quantum dots. Further, the quantum dots can be connected to each other through surface modification groups. As shown in FIG. 5, when the QLED adopts a stacked structure, the emission functional unit EFU can also be provided with a charge generation layer CGL.

In some embodiments of the present disclosure, as shown in FIGS. 2 to 5, the emission functional unit EFU can include a single layer of light-emitting stacked structure ELS or multiple layers of light-emitting stacked structures ELS. When the emission functional unit EFU includes multiple layers of light-emitting stacked structures ELS, a charge generation layer CGL can be arranged between adjacent two layers of light-emitting stacked structures ELS. Each layer of light-emitting stacked structure ELS is provided with one or more light-emitting layers, which can be either the organic emission layer or the quantum dot luminescent layer.

In the embodiments shown in FIGS. 2 and 3, the emission functional unit EFU has a single layer of light-emitting stacked structure ELS. As shown in FIGS. 2 and 3, the thin-film light-emitting device includes an anode AE, a light-emitting stacked structure ELS, and a cathode CE, which are stacked in sequence. The light-emitting stacked structure ELS includes a hole adjustment part, a light-emitting layer (such as an organic emission layer EML or a quantum dot luminescent layer QDL), and an electron adjustment part stacked in sequence. The hole adjustment part is located on a side of the light-emitting layer close to the anode, and the electron adjustment part is located on a side of the light-emitting layer close to the cathode. The anode is used to inject holes into the light-emitting layer through the hole adjustment part, and the cathode is used to inject electrons into the light-emitting layer through the electron adjustment part. The hole adjustment part and the electron adjustment part are respectively used to adjust injection efficiencies and injection rates of holes and electrons injected into the light-emitting layer, as well as to adjust the energy levels of the injected electrons and holes, thereby improving the balance between hole injection and electron injection, and further enhancing the performance of the emission functional unit EFU, such as improving the light-emitting efficiency of the thin-film light-emitting device, and/or extending the device lifetime of the thin-film light-emitting device, and/or reducing the power supply voltage of the thin-film light-emitting device.

The hole adjustment part can include one or more film layers such as the hole injection layer, the hole transport layer HTL, and the electron blocking layer EBL, and at least includes the hole transport layer HTL. The hole injection layer, the hole transport layer HTL, and the electron blocking layer EBL are sequentially stacked in the direction from the anode to the light-emitting layer. It can be understood that in some embodiments, one or more film layers such as the hole injection layer, the hole transport layer HTL, and the electron blocking layer EBL can be configured as a multi-layer stacked structure. For example, the hole transport layer HTL can include a first-type hole transport layer and a second-type hole transport layer that are arranged in a stacked manner.

The electron adjustment part can include one or more film layers such as the electron injection layer EIL, the electron transport layer ETL, and the hole blocking layer HBL. The electron injection layer EIL, the electron transport layer ETL, and the hole blocking layer HBL are sequentially stacked in the direction from the cathode to the light-emitting layer. It can be understood that in some embodiments, one or more film layers such as the electron injection layer EIL, the electron transport layer ETL, and the hole blocking layer HBL can be configured as a multi-layer stacked structure. For example, the electron transport layer ETL can include a first-type electron transport layer and a second-type electron transport layer that are arranged in a stacked manner.

In the embodiments shown in FIGS. 4 and 5, the emission functional unit EFU has multiple layers of light-emitting stacked structures ELS (FIGS. 4 and 5 illustrate two layers of light-emitting stacked structures ELS). As shown in FIGS. 4 and 5, the thin-film light-emitting device includes an anode, multiple layers of light-emitting stacked structures ELS, and a cathode, which are stacked in sequence. Any layer of the multiple layers of light-emitting stacked structures ELS includes sequentially stacked hole adjustment part, light-emitting layer (such as an organic emission layer or a quantum dot luminescent layer), and electron adjustment part. The hole adjustment part is located on a side of the light-emitting layer close to the anode, and the electron adjustment part is located on a side of the light-emitting layer close to the cathode.

In some embodiments, the emission functional unit EFU can further include a charge generation layer CGL located between two adjacent light-emitting stacked structures ELS, to improve the efficiency of injecting electrons and holes into the two adjacent light-emitting stacked structures ELS. For example, the charge generation layer CGL includes an N-type charge generation layer (NCGL) and a P-type charge generation layer (PCGL) stacked between the two adjacent light-emitting stacked structures ELS. The N-type charge generation layer (NCGL) is arranged adjacent to the electron adjustment part of one of the light-emitting stacked structures ELS for injecting electrons into the electron adjustment part of the light-emitting stacked structure ELS. The P-type charge generation layer (PCGL) is arranged adjacent to the hole adjustment part of the other light-emitting stacked structure ELS for injecting holes into the hole adjustment part of that light-emitting stacked structure ELS. In other words, the P-type charge generation layer (PCGL) is arranged on a side of the N-type charge generation layer (NCGL) away from the anode. It should be understandable that in other embodiments, the charge generation layer CGL can further include other structures.

It can be understood that in some other embodiments of the present disclosure, the electron adjustment part of the light-emitting stacked structure ELS can be omitted, or the light-emitting stacked structure ELS can also have other structures besides the electron injection layer EIL, the electron transport layer ETL, and the hole blocking layer HBL.

It can be understood that when multiple light-emitting layers are arranged in the light-emitting stacked structure ELS, colors of these light-emitting layers can be the same or different, and types of these light-emitting layers can also be the same or different.

It can be understood that for any one of the light-emitting stacked structures ELS, it can be provided with a light-emitting layer (such as a quantum dot luminescent layer or an organic emission layer), and it can also be provided with one or more of a hole injection layer, a hole transport layer HTL, an electron blocking layer EBL, a hole blocking layer HBL, an electron transport layer ETL, and an electron injection layer EIL, or other film layers can be added as needed. In some embodiments, in the light-emitting stacked structure ELS, one or more of the hole injection layer, the electron blocking layer EBL, the hole blocking layer HBL, the electron transport layer ETL, and the electron injection layer EIL can also be omitted. For two light-emitting stacked structures ELS of a thin-film light-emitting device, the film layer structures of the two light-emitting stacked structures ELS can be the same or different.

In some embodiments of the present disclosure, the thin-film light-emitting device includes an anode, a hole transport layer, a light-emitting layer, and a cathode, which are sequentially stacked. The hole transport material of the hole transport layer adopts organic semiconductor materials, such as organic small molecule semiconductor materials or polymer semiconductor materials. When electrons leak into this hole transport layer, excitons are formed, which include triplet excitons and singlet excitons.

The typical lifetime of a singlet exciton is relatively short (e.g., 1-10 ns), allowing the singlet exciton to decay spontaneously relatively quickly. However, due to the limitation by the selection rule of angular momentum conservation, the lifetime of the triplet exciton is longer, reaching the order of microseconds or even milliseconds. Moreover, from a statistical perspective, the formation probability of the triplet exciton is 75%, which is also higher than the 25% formation probability of the singlet exciton. These factors result in a much higher concentration of triplet excitons in the hole transport layer compared to singlet excitons. The triplet exciton can affect the stability of the hole transport layer in various ways. Under appropriate energy levels, the triplet exciton can react with trace amounts of oxygen in the film to form singlet oxygen, which can attack the unsaturated C—C bond in the hole transport layer. The triplet exciton can also undergo the quenching reaction with the carrier in the hole transport layer, generating a high-energy carrier or an excited state, so that the triplet exciton has sufficient energy to attack various chemical bonds in the hole transport layer. The triplet exciton may also react with another triplet exciton or singlet exciton, generating the same high-energy state to damage the hole transport layer.

In some embodiments of the present disclosure, the hole transport layer HTL can include not only hole transport materials but also triplet quenching materials. These triplet quenching materials can quench at least some of the triplet excitons in the hole transport materials. Specifically, the triplet quenching materials can capture the triplet excitons in the hole transport layer HTL, convert them into non-destructive final states, thereby reducing the damage caused by the triplet excitons to the hole transport materials, slowing down the aging rate of the hole transport layer HTL, and extending the lifetime of the thin-film light-emitting device.

In some embodiments, the triplet quenching materials capture the triplet excitons through the Dexter charge transfer mechanism or the collisional energy exchange mechanism. Further, the triplet quenching materials can capture triplet excitons within a 1 nm radius around it.

In some embodiments of the present disclosure, the thin-film light-emitting device is a blue thin-film light-emitting device. Compared to red and green thin-film light-emitting devices, the hole transport layer of the blue thin-film light-emitting device is more prone to being damaged. Therefore, introducing a triplet quenching material into the hole transport layer of the blue thin-film light-emitting device to enhance the lifetime of the blue thin-film light-emitting device, can more effectively alleviate the constraints that the blue thin-film light-emitting devices impose on the life lifetime of the display panel or light-emitting panel.

In some embodiments of the present disclosure, the thin-film light-emitting device is a QLED, where the light-emitting layer is a quantum dot luminescent layer. In some embodiments, the hole electron transport layer can be made of inorganic semiconductor materials, such as zinc oxide or magnesium oxide, and the hole transport material is an organic semiconductor material. This makes the hole transport layer the most vulnerable film layer in the QLED, thereby limiting the device's lifetime. In some embodiments of the present disclosure, by adding a triplet quenching material to the hole transport layer to improve its stability, the lifetime of the QLED can be improved.

In some embodiments of the present disclosure, the HOMO (Highest Occupied Molecular Orbital) energy level of the triplet quenching material is not greater than the HOMO energy level of the hole transport material. In this way, compared to the hole transport material, the triplet quenching material has a deeper HOMO energy level, which can avoid the generation of hole traps in the hole transport layer and ensure smooth hole transport in the hole transport layer. For example, taking the hole transport material TFB (Poly[(9,9-dioctylfluorenyl-2,7-diyl)-alt-(4,4′-(N-(4-butylphenyl)) as an example, its HOMO energy level is −5.4 eV, so the HOMO energy level of the triplet quenching material can be no greater than −5.4 eV. In other embodiments of the present disclosure, the HOMO energy level can also be slightly higher than −5.4 eV, subject to not introducing significant hole traps.

In some embodiments of the present disclosure, the difference between the LUMO (Lowest Unoccupied Molecular Orbital) energy level of the triplet quenching material and the LUMO energy level of the hole transport material is not less than −1 eV. This can prevent the LUMO energy level of the triplet quenching material from being too low, which could lead to a significant electron leakage path. For example, if the hole transport material is TFB with a LUMO energy level of −2.8 eV, the LUMO energy level of the triplet quenching material can be no less than −3.8 eV.

Further, the LUMO energy level of the triplet quenching material is higher than the LUMO energy level of the hole transport material. In this way, the possibility of forming an electron leakage path can be further reduced.

In some embodiments of the present disclosure, the mobility of the triplet quenching material is lower than the mobility of the hole transport material. In this way, the impact of the triplet quenching material on the hole transport performance of the hole transport layer can be reduced. When conditions permit, the hole mobility can be minimized as much as possible, for example, the hole mobility is minimized such that the hole mobility of the triplet quenching material is less than 1 e⁻⁵ cm/V/S.

In some embodiments of the present disclosure, the triplet energy level of the triplet quenching material is lower than the triplet energy level of the hole transport material. Thus, triplet excitons on the hole transport material can be transferred to the triplet quenching material, achieving the quenching of the triplet excitons on the hole transport material without overcoming an energy level barrier.

In some embodiments of the present disclosure, a rate at which the triplet quenching material transitions from the triplet state to the ground state is greater than a rate at which the hole transport material transitions from the triplet state to the ground state.

In some embodiments of the present disclosure, the singlet energy level of the triplet quenching material is higher than the singlet energy level of the hole transport material. In this way, the triplet quenching material does not affect the transport and blocking property of the singlet exciton of the hole transport material, and can better maintain the singlet property in the host.

In some embodiments of the present disclosure, a mass ratio of the triplet quenching material in the hole transport layer ranges from 0.0001% to 90%. Further, the mass ratio of the triplet quenching material in the hole transport layer is between 1% and 30%, such as 1%, 2%, 5%, 10%, 15%, 20%, 25%, and 30%. This can maintain the hole transport performance of the hole transport layer as much as possible while reducing the risk of the damage to the hole transport material caused by the triplet exciton.

In some embodiments of the present disclosure, in the hole transport layer, the hole transport material and the triplet quenching material are two separate materials, meaning that they are not linked through strong chemical bonds such as covalent bonds. The triplet quenching material is uniformly dispersed in the hole transport layer. In some embodiments, a solution containing the hole transport material and the triplet quenching material can be used as a raw material to form the hole transport layer through solution processes such as coating, spin coating, printing, or inkjet printing. In some embodiments, the hole transport layer can be formed through co-evaporation of the hole transport material and the triplet quenching material, and the evaporation rate of the hole transport material and the triplet quenching material determines the content of the triplet quenching material in the hole transport layer.

In some embodiments, the following method can be used to prepare the hole transport layer: dissolving the hole transport material and the triplet quenching material in a solvent to obtain a precursor solution; and using the precursor solution to prepare the hole transport layer through a coating process (such as spin coating process), a screen printing process, or an inkjet printing process. In this embodiment, the selections of the hole transport material, the triplet quenching material, and the solvent need to ensure that both the hole transport material and the triplet quenching material can be uniformly and non-aggregatively distributed in the solution, thereby facilitating the formation of a film layer with a uniform thickness.

In some embodiments, the following method can be used to prepare the hole transport layer: forming the hole transport layer through a co-evaporation process using the hole transport material and the triplet quenching material.

For example, the hole transport material and the triplet quenching material can be respectively placed in an evaporation cell 1 and an evaporation cell 2. The evaporation rate of the hole transport material is controlled between 0.1 angstroms and 10 nanometers per minute, and the evaporation rate of the triplet quenching material is controlled between 0.1 angstroms and 10 nanometers per minute. In this way, the evaporation rate ratio of the hole transport material to the triplet quenching material can be controlled between 1:1 and 1000:1 according to different doping designs. In this embodiment, the melting point of the triplet quenching material can be made less than 800° C. to ensure that the triplet quenching material can evaporate effectively.

In some embodiments of the present disclosure, the hole transport material and the triplet quenching material crosslink with each other to form a multifunctional polymer, which enables the multifunctional polymer to have both fragments for the hole transport and fragments for quenching triplet excitons. In some embodiments, the chemical formula of the multifunctional polymer is [A]ₓ[B]_{y}, where A represents a monomer of a hole transport conductive polymer, B represents the triplet quenching material or its monomer, x represents the number of A repeat units, and y represents the number of triplet quenching material or its monomer repeat units. The polymer can be a random dimer polymer, a diblock polymer, or an alternating polymer.

In this way, the multifunctional polymer can be directly used as the hole transport layer, and the hole transport material and the triplet quenching material are both integrated into the multifunctional polymer, which can ensure the material ratio and the distribution uniformity of the triplet quenching material in the hole transport layer.

In some embodiments, A can be a TFB monomer, a PVK (Poly(N-vinyl carbazole)) monomer, a TPD (N,N′-bis(3-methylphenyl)-N,N′-diphenyl-benzidine), or other monomers.

It can be understood that in this multifunctional polymer, B can be directly a monomer of the triplet quenching material, or a functionalized triplet quenching material. The functionalized triplet quenching material introduces a condensation functional group (such as a double bond, an isocyanate group, etc.) on the monomer of the triplet quenching material, so that the functionalized triplet quenching material can polymerize with A.

In some embodiments, chemical synthesis can be used to link the triplet quenching material to the polymer that serves as the hole transport material, to form a new polymer.

In some embodiments, the monomers of the triplet quenching material and the hole transport material can undergo polymerization reaction together to generate the desired polymer.

In some embodiments, the following method can be used to prepare the hole transport layer: polymerizing the monomer of the hole transport material and the monomer of the triplet quenching material together to form a multifunctional polymer; dissolving the multifunctional polymer in a solvent to obtain a precursor solution; and preparing the hole transport layer using the precursor solution through a coating process, a screen printing process or an inkjet printing process.

In some embodiments, the triplet quenching material and at least a portion of the hole transport material are linked through a chemical bond or a linking group. In this embodiment, the multifunctional material can be synthesized first, which is a material formed by linking the hole transport material with the triplet quenching material through the chemical bond or the linking group. For example, a structure of the multifunctional material is formed by directly linking the hole transport material with the triplet quenching material through the chemical bond (such as a single bond), or by linking the hole transport material with the triplet quenching material through the linking group (such as methylene, phenylene, etc.). It can be understood that it is not necessarily required to use hole transport materials and triplet quenching materials as raw materials to synthesize the required multifunctional material, as long as the structure of the synthesized material exhibits interlinking of the hole transport material and the triplet quenching material in the multifunctional material. The multifunctional material has both hole transport function and triplet quenching function. When preparing the hole transport layer, hole transport materials and multifunctional materials can be used as raw materials. For example, the hole transport layer is formed through co-evaporation using a mixture of hole transport materials and multifunctional materials (vapor deposition materials).

For example, the hole transport material is A, the triplet quenching material is B, and the multifunctional material is A−B. When preparing the hole transport layer through the evaporation process, the material of the evaporation source is A with a mass fraction of x and A−B with a mass fraction of 1−a, where x is a positive number less than 1. By adjusting a, the mass fraction of the triplet quenching material in the hole transport layer can be adjusted.

It can be understood that a multifunctional material can have a triplet quenching material attached, or a multifunctional material can have multiple triplet quenching materials attached.

In some embodiments, the following method can be used to prepare the hole transport layer: synthesizing the multifunctional material, wherein the multifunctional material is formed by linking the hole transport material with the triplet quenching material through a chemical bond or a linking group; mixing the multifunctional material and the hole transport material uniformly to form a vapor deposition material; and forming the hole transport layer through a vapor deposition process using the vapor deposition material.

In some embodiments, the triplet quenching material includes one or more of transition metal derivatives, biphenyl, biphenyl derivatives, cyclooctadiene, cyclooctadiene derivatives, cyclooctene, cyclooctene derivatives, organic small molecule semiconductor materials, and high polymer semiconductor materials.

In some embodiments of the present disclosure, the transition metal derivative can be a transition metal chelate. For example, the transition metal derivative can be a nickel derivative, especially a nickel chelate. Alternatively, the transition metal derivative can also be other transition metal chelates, such as a zinc chelate.

In some embodiments, the triplet quenching material is selected from the following compounds:

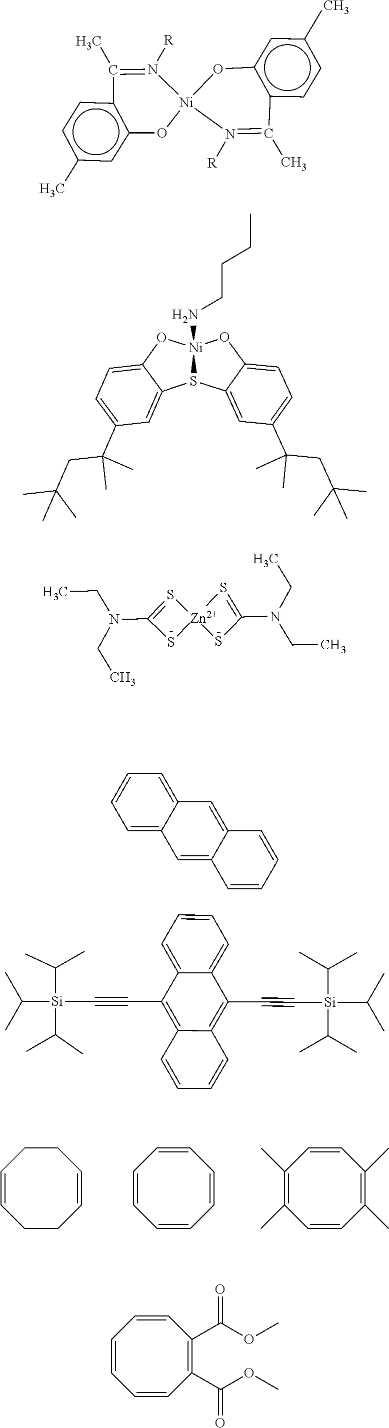

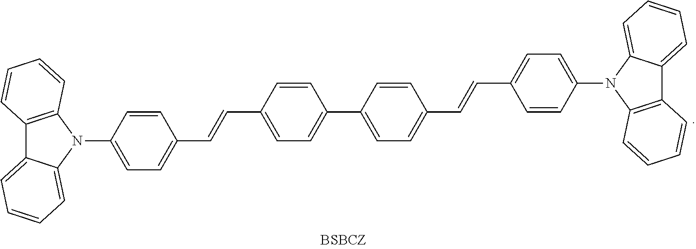 [SMILES: C(=C\c1ccc(-n2c3ccccc3c3ccccc32)cc1)/c1ccc(-c2ccc(/C=C/c3ccc(-n4c5ccccc5c5ccccc54)cc3)cc2)cc1]

The nickel chelate has multiple triplet quenching mechanisms, which can quench a triplet exciton at least 1.1 eV without affecting the singlet exciton in the hole transport material. The quenching rate of the nickel chelate can reach 10⁸ moles per second. Moreover, the nickel chelate can sometimes quench free radicals and decompose peroxides, further enhancing the protective effect on the hole transport material.

The benzo and its derivative typically have a significant energy level difference between singlet and triplet states, allowing them to quench the triplet state in the hole transport material while preserving the singlet state efficiently. For example, the singlet energy level of anthracene is 3.1 eV, and the triplet energy level is 1.78 eV

The cyclooctene (COT) is a non-classical triplet quencher. In addition to a high triplet excited state (energy level of 2.56 eV), the cyclooctene has a very low triplet energy level (energy level of 0.8 eV) in the relaxation state, which can effectively quench the triplet states in the host material. At the same time, the singlet energy level of the cyclooctene is relatively high (reaching 4.39 eV), which does not affect the singlet state in the hole transport material and the charge transfer in the hole transport material. The triplet lifetime of the cyclooctene is relatively short compared to anthracene, and the cyclooctene can quickly decay the triplet state received from the hole transport material.

The BSBCZ has a low triplet energy level (1.48 eV) and a high singlet energy level (2.97 eV). The BSBCZ is a representative of the small molecule or the high polymer semiconductor material that can be more traditional and widely used as the triplet quencher. The energy level of such triplet quencher needs to meet certain matching conditions with the energy level of the hole transport material. For example, the triplet energy level of the triplet quencher should be lower than the triplet energy level of the hole transport material. In an ideal situation, the singlet energy level of the triplet quencher should be higher than the singlet energy level of the hole transport material, the HOMO energy level of the triplet quencher should be lower than the HOMO energy level of the hole transport material, and the LUMO energy level of the triplet quencher should be higher than the LUMO energy level of the hole transport material.

In some embodiments of the present disclosure, the triplet quenching material includes a linking group and at least one quenching group attached to the linking group, and the structure of the quenching group is selected from the following structures:

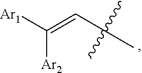

where Ar₁ and Ar₂ are independently selected from substituted or unsubstituted aryl with 6-30 carbon atoms, and substituted or unsubstituted heteroaryl with 4-30 carbon atoms.

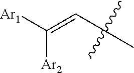

In the embodiment, the functional group Ar₂ allows suitable HOMO, LUMO, singlet, and triplet energy levels to be obtained in the triplet quenching material.

In some embodiments of the present disclosure, the substituents on Ar₁ and Ar₂ can each be independently selected from deuterium, methyl, ethyl, isopropyl, methoxy, ethoxy, cyclohexyl, cyclopentyl, and adamantyl.

In some embodiments of the present disclosure, the quenching group of the triplet quenching material is selected from

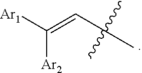

The linking group of the triplet quenching material has an aromatic structure (such as a benzene ring, a fluorene ring, a naphthalene ring, etc.), and the quenching group is directly attached to the aromatic structure. In this way, the aromatic structure on the linking group conjugates with the

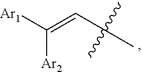

so as to adjust the HOMO, LUMO, singlet, and triplet energy levels, etc. of the triplet quenching material, achieving a better match between the triplet quenching material and the energy level of the hole transport material.

In some embodiments, Ar₁ and Ar₂ are each independently selected from substituted or unsubstituted phenyl, substituted or unsubstituted naphthyl, and substituted or unsubstituted biphenyl. When Ar₁ or Ar₂ has a substituent, any substituent is selected from deuterium, methyl, ethyl, and isopropyl. For example, Ar₁ and Ar₂ are each independently selected from deuterium substituted or unsubstituted phenyl, deuterium substituted or unsubstituted naphthyl, and deuterium substituted or unsubstituted biphenyl.

In some embodiments, the linking group is selected from substituted or unsubstituted biphenyl, substituted or unsubstituted spirofluorenyl, substituted or unsubstituted triphenyl, substituted or unsubstituted naphthyl, substituted or unsubstituted anthracene, substituted or unsubstituted phenanthrene, and substituted or unsubstituted phenyl. When the linking group has a substituent, any substituent is independently selected from deuterium, methyl, ethyl, and isopropyl. For example, the linking group is selected from deuterium substituted or unsubstituted biphenyl, deuterium substituted or unsubstituted spirofluorenyl, deuterium substituted or unsubstituted triphenyl, deuterium substituted or unsubstituted naphthyl, deuterium substituted or unsubstituted anthracene, deuterium substituted or unsubstituted phenanthrene, and deuterium substituted or unsubstituted phenyl.

In some embodiments of the present disclosure, the number of quenching groups in the triplet quenching material is 2-4. In this way, on the one hand, the energy level of the triplet quenching material can be adjusted via the mutual influence between quenching groups. On the other hand, it can improve the quenching efficiency of the triplet quenching material, which is beneficial for improving the stability of the triplet quenching material itself. In addition, this is beneficial for reducing the doping amount of triplet quenching materials in the hole transport layer, and reducing the influence of the triplet quenching material on the hole transport performance of the hole transport layer.

In some embodiments, the triplet quenching material is selected from 4,4′-Bis(2,2-diphenylethenyl)-1,1′-biphenyl (compound DPVBi) and 2,2′,7,7′-Tetrakis(2,2-diphenylethenyl)-9,9′-spirobifluorene (compound Spiro-DPVBi).

The structures of compound DPVBi and compound Spiro-DPVBi are as follows:

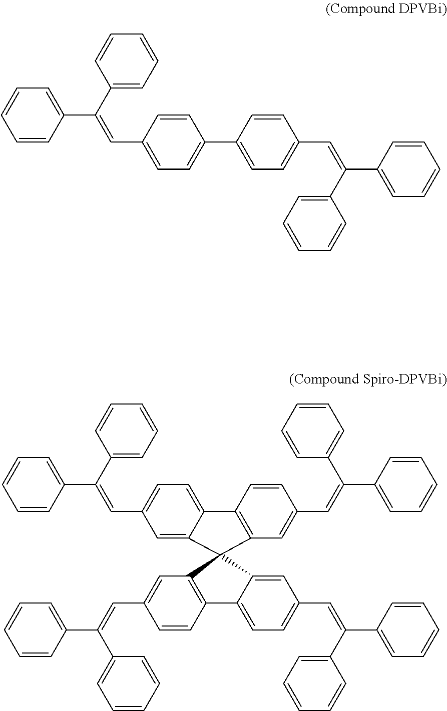

In some embodiments, compound Spiro-DPVBi is a spiro derivative of compound DPVBi. In other embodiments, the triplet quenching material can also be other derivatives of compound DPVBi, such as a derivative by linking compound DPVBi with the hole transport material through a chemical bond or a linking group, or a derivative by replacing compound DPVBi with alkyl, aryl, heteroaryl, deuterium, etc. The derivatives of compound DPVBi can preserve the energy level property similar to compound DPVBi, while achieving improvements in some properties, such as the improved film-forming property.

Compound DPVBi and its derivative structures will be illustrated by taking the property parameters of compound DPVBi and compound Spiro-DPVBi as examples. In the embodiment, the high polymer TFB (Poly[(9,9-dioctylfluorenyl-2,7-diyl)-alt-(4,4′-(N-(4-butylphenyl)) is used as the hole transport material.

In the embodiment, for compound DPVBi, the S1 energy level is 3.1 eV, the T1 energy level is 2.2 eV, the LUMO energy level is −2.8 eV, and the HOMO energy level is −5.8 eV For compound Spiro-DPVBi, the T1 energy level is 1.98 eV, the LUMO energy level is −2.4 eV, and the HOMO energy level is −5.4 eV. Correspondingly, for compound TFB, the S1 energy level is 2.8 eV, the Ti energy level is 2.3 eV, the LUMO energy level is −2.8 eV, and the HOMO energy level is −5.4 eV

In this way, when compound DPVBi is used in combination with compound TFB, compound TFB can serve as the hole transport material, and compound DPVBi can serve as the triplet quenching material. The HOMO energy level of compound DPVBi is lower than the HOMO energy level of compound TFB. The LUMO energy level of compound DPVBi is not lower than the LUMO energy level of compound TFB. The T1 energy level of compound DPVBi is lower than that of compound TFB. The S1 energy level of compound DPVBi is higher than the Si energy level of compound TFB.

In some embodiments of the present disclosure, a test device (red QLED device) is prepared and tested according to the following method.
Step A1) solution preparation: preparing a PEDOT:PSS solution, preparing a mixed solution of TFB and DPVBi (12 mg/mL, chlorobenzene solvent, three different mixed solutions, with a mass ratio of DPVBi relative to (DPVBi+TFB) in different mixed solutions is varied at 0%, 2%, and 10%), and preparing a solution of ZnO nanoparticles (in isopropanol solvent).
Step A2) substrate preparation: cleaning an ITO patterned substrate using water ultrasonic cleaning for 600 seconds and isopropanol ultrasonic cleaning for 300 seconds, and performing UV Ozone treatment for 15 minutes.
Step A3) spin coating hole injection layer: spin coating a PEDOT:PSS hole injection layer at 3000 rpm (spin coating speed) for 1 minute.
Step A4) transferring to an inert environment: thoroughly purging the glovebox to ensure low oxygen and water concentration, and transferring the device to an inert environment.
Step A5) spin coating hole transport layer: spin coating the prepared TFB:DPVBi mixed solution at 2000 rpm (spin coating speed) for 1 minute, and annealing at 120° C. for 10 minutes.
Step A6) spin coating quantum dot luminescent layer: spin coating using a solution with a concentration of 20 mg/ml, at 2000 rpm (spin coating speed), for 1 minute, and annealing at 100° C. for 10 minutes.
Step A7) spin coating ZnO nanoparticle material: spin coating at 2000 rpm (spin coating speed) for 1 minute, and annealing at 100° C. for 10 minutes.
Step A8) vacuum thermal evaporating A1 to a thickness of 100 nm as the top electrode.
Step A9) using glass plates and epoxy resin for packaging and testing.

In this embodiment, nominally identical test devices A, B, and C are prepared. The only difference between test devices A, B, and C is the mass ratio (referred to as doping ratio, for convenience of describing embodiments of the present disclosure) of DPVBi relative to the total mass of DPVBi and TFB in the hole transport layer, which is 0%, 2%, and 10%, respectively.

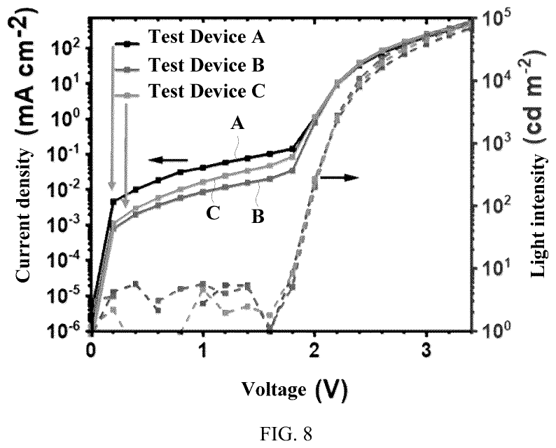

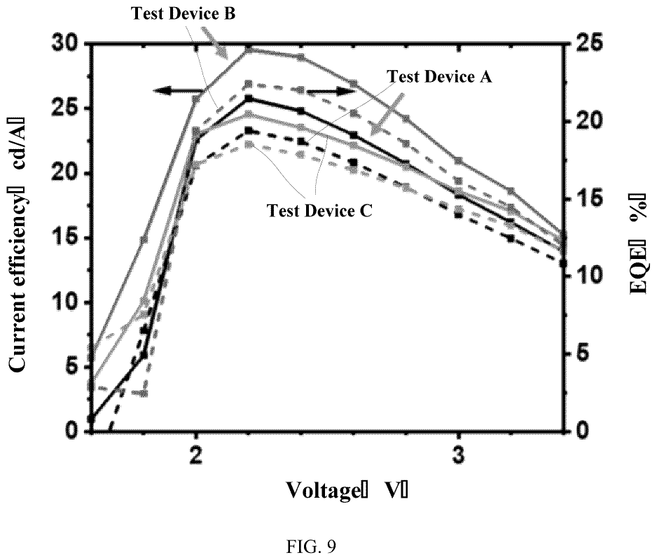

FIG. 8 shows current vs. voltage curves and luminance vs. voltage curves of Test Device A, Test Device B, and Test Device C. As shown in FIG. 8, compared to Test Device A, forward leakage currents of Test Device B and Test Device C are both significantly reduced before turning on (about 1.8 V), with the reduction of Test Device B reaching or even exceeding an order of magnitude. Meanwhile, after the device is turned on, there is no decrease in the forward turned-on current of Test Device B and Test Device C, which indicates that the addition of DPVBi does not affect the charge transport of the device.

FIG. 9 shows current efficiency vs. voltage curves and external quantum efficiency (EQE) vs. voltage curves of Test Device A, Test Device B, and Test Device C. As shown in FIG. 9, the peak EQE of Test Device A is approximately 19%, and the peak EQE of Test Device B increases to approximately 22.5%, with an increase percentage of 18%. The peak EQE of Test Device C is approximately 18%, indicating that excessive doping of DPVBi may affect the external quantum efficiency. For example, when the doping amount of DPVBi is moderate, its deeper HOMO energy level can be used to improve the hole injection, while excessive doping of DPVBi may degrade the hole transport capability of the hole transport layer, thereby affecting charge balance.

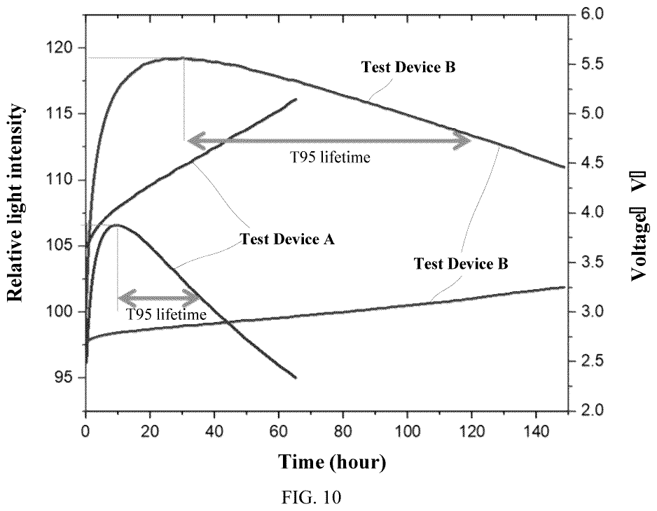

FIG. 10 shows life test results and voltage test results of Test Device A and Test Device B. In this test, both devices are operated at a high luminance (both close to 10000 nits), and the changes in voltage and luminance over time are detected. According to FIG. 10, it can be seen that the T95 lifetime of Test Device A (the time for luminance to decay to 95% of maximum luminance) is greater than 25 hours, while the T95 lifetime of Test Device B is greater than 90 hours. Therefore, the lifetime of devices doped with DPVBi is significantly improved. Meanwhile, considering the nearly 18% increase in external quantum efficiency, the improvement in device lifetime mainly comes from the enhancement of the stability of the hole transport layer.

In the above embodiments, devices with hole transport layers doped with 2% DPVBi and 10% DPVBi are prepared and tested. It can be understood that devices with other doping ratios can also be prepared, such as those with doping ratios of 0.5%, 1%, 1.5%, 2.5%, 3%, 3.5% 4%, 4.50 5%0, 5.5%, 6%, 6.5%, 7%, 7.5% 8%, 8.5%, 9% 9.5%.

In the above embodiments, the chlorobenzene is used as a solvent in the preparation of the hole transport layer. In some other embodiments of the present disclosure, the solvent can also be varied, so that the distribution of DPVBi in the hole transport layer and on the surface can be adjusted, thereby further optimizing the performance of the device.

In some embodiments, after forming the hole transport layer, the surface of the hole transport layer can be rinsed with a rinsing solvent to adjust the DPVBi concentration on the surface of the hole transport layer, such as reducing the DPVBi at the interface between the hole transport layer and the quantum dot luminescent layer, which is beneficial for optimizing the energy level arrangement at the interface, such as reducing the leakage current that may be caused by DPVBi. In some embodiments, a solvent with a different polarity compared to the solvent in the mixed solution of TFB and DPVBi can be used to rinse the surface of the hole transport layer, or a solvent with a different polarity compared to the solvent in the quantum dot solution (such as octane) can be used to rinse the surface of the hole transport layer.

In some embodiments, for better performance, the method described above can be further optimized by replacing DPVBi with Spiro-DPVBi. Compared to DPVBi, Spiro-DPVBi has the following advantages.

a) The energy level matching is relatively good, which facilitates better triplet quenching. The triplet energy level of Spiro-DPVBi is 1.98 eV, which is substantially higher than the triplet energy level of TFB. From an energy dynamics perspective, more effective quenching of triplet excitons can be achieved.

b) The molecular volume is larger, at least twice as large as DPVBi, with better film-forming performance and the ability to prevent the crystallization of transport materials. Especially for crystalline hole transport materials, the high molecular weight (up to the order of kg/mol) and large volume (approximately 2-3 nm) of Spiro-DPVBi with a bond length of over 10 atoms can effectively interfere with the crystallization of the hole transport material and improve the flatness of film formation.

In some embodiments of the present disclosure, the triplet quenching material includes a linking group and at least one quenching group attached to the linking group, and the structure of the quenching group is selected from the following structure:

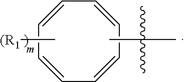

R₁ is selected from deuterium, alkyloxycarbonyl with 1-18 carbon atoms, alkylcarbonyl with 1-18 carbon atoms, alkoxyl with 1-18 carbon atoms, alkyl with 1-18 carbon atoms, cycloalkoxycarbonyl with 5-10 carbon atoms, cycloalkylcarbonyl with 5-10 carbon atoms, cycloalkoxy with 5-10 carbon atoms, cycloalkyl with 5-10 carbon atoms, substituted or unsubstituted aryl with 6-18 carbon atoms, and substituted or unsubstituted heteroaryl with 4-18 carbon atoms, and m is a positive integer selected from 0 to 7.

In some embodiments, the triplet quenching material is a COT (cyclooctatetraene) derivative, which posses a triplet quenching effect. In some embodiments, the substituent and the linking group on the cyclooctatetraene group can adjust various energy levels, physical properties (such as melting point, volume, boiling point, etc.), and chemical properties (such as electrochemical stability, aging rate), etc. of the triplet quenching material, enabling the physicochemical properties and energy levels of the triplet quenching material to be matched with the hole transport material.

In embodiments of the present disclosure, the molecular weight of the triplet quenching material is between 600 and 1200. In this way, the problem of low melting point (which can lead to a low glass transition temperature of the film layer) of the triplet quenching material can be avoided, which is conducive to improving the film stability of the hole transport layer.

In embodiments of the present disclosure, the linking group is an organic semiconductor structure having hole transport properties, or the linking group is a flexible linking group with at least two flexible arms, and any one of the flexible arms is attached to one of quenching groups.

For example, in some embodiments, one or more

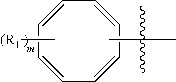

can be functionalized on a triarylamine compound, which can enable the triarylamine compound to possess a triplet quenching effect. Further,

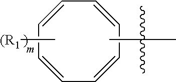

is attached to the triarylamine compound through a non-conjugated bond, to reduce a conjugation impact on the energy level of COT.

For example, in some embodiments, the linking group can have a central quaternary carbon with four flexible arms (such as alkyl arms) attached to the central quaternary carbon, and an end of each flexible arm is attached with

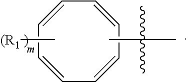

This can modify COT while increasing the concentration of COT groups, thereby improving the triplet quenching effect.

The present disclosure also provides verification examples to verify the protective effect of adding triplet quenching materials to hole transport materials.

### First Verification Example

The hole transport material adopts the high polymer TFB (Poly[(9,9-dioctylfluorenyl-2,7-diyl)-alt-(4,4′-(N-(4-butylphenyl)), and the triplet quenching material adopts UV-1084 (2,2′-Thiobis(4-tert-octylphenylto)-n-butylamine nickel(II).

The structure of UV-1084 is shown as follows:

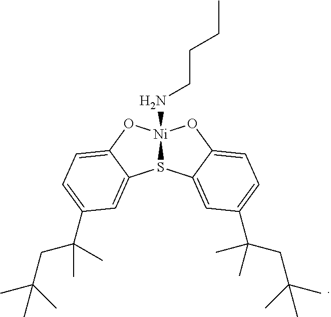

The precursor solution for the hole transport layer is obtained by co-dissolving the hole transport material and the triplet quenching material in the chlorobenzene. An TO patterned glass substrate is first treated with UV and ozone. Subsequently, the PEDOT:PSS is spin coated at 3000 rpm (spin coating speed) for 1 minute, and then annealed at 150° C. in air for 30 minutes to form the hole injection layer. The device is then transferred to an inert environment. The above precursor solution for the hole transport layer is spin coated. The material concentration (hole transport material+triplet quenching material) in the precursor solution is 12 mg/mL, the spin coating speed is 2000 rpm, and the spin coating time is for 1 minute. The hole transport layer thin film for testing is then obtained after being annealed at 120° C. for 10 minutes.

In this verification example, a first verification film, a second verification film, and a first reference film are prepared. The mass proportion of the triplet quenching material in the first verification film is 5%, and the mass proportion of the triplet quenching material in the second verification film is 10%. The first reference film does not contain the triplet quenching material.

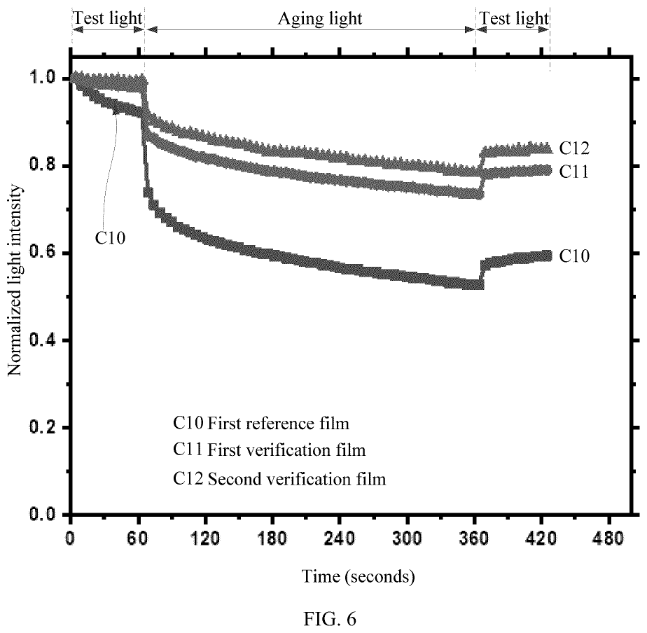

The first verification film, the second verification film, and the reference film are sequentially irradiated with test light (low intensity), aging light (high intensity), and test light (low intensity), with a wavelength of 405 nanometers. At the same time, the intensity of the light emitted by the hole transport material after excitation is detected, which can reflect the degree of damage to the hole transport material. The stronger the light intensity, the smaller the damage to the hole transport material, and the better the protective effect of the triplet quenching material on the hole transport material. The hole transport material generates photogenerated excitons upon exposure to the light irradiation, and the triplet quenching material can protect the hole transport material by quenching triplet excitons. The verification test results are shown in FIG. 6.

As shown in FIG. 6, when the thin film is irradiated with low-intensity test light, all three types of thin films are excited and emit light under the light irradiation. However, it is evident that the intensity of the first reference film C10 without the addition of triplet quenching materials decreases relatively quickly, while the intensity of the first validation film C11 and the second validation film C12 is better maintained. This indicates that the triplet quenching material possesses a good protective effect on the hole transport material. When the film is irradiated with high-intensity aging light, the intensities of the three films, in descending order, are the second verification film C12, the first verification film C11, and the first reference film C10. This indicates that the stability of the film with the addition of triplet quenching materials is significantly improved under strong light, and the stability of the film is correlated with the amount of the triplet quenching material added. Within a certain content range, the more the amount of the triplet quenching material added, the better the stability of the hole transport material.

In the above verification example, the intensity of the test light is 100 mW/cm². The intensity of the aging light is 10 W/cm². It can be understood that the intensity of the test light and the intensity of the aging light can be adjusted as needed, so that the intensity of the aging light is set to be 10-1000 times that of the test light, for example, the intensity of the aging light is 100 times that of the test light. In some examples, the intensity of the test light ranges from 0.1 to 100 mW/cm², and the intensity of the aging light ranges from 5 mW/cm² to 100 W/cm².

### Second Verification Example

A second reference film, a third verification film, a fourth verification film, a fifth verification film, and a sixth verification film are prepared according to the first verification example. The second reference film does not contain the triplet quenching material, and the hole transport material is TFB. The triplet quenching material in the third verification film, the fourth verification film, the fifth verification film, and the sixth verification film is dimethyl 1,3,5,7-cyclooctatetraene-1,2-dicarboxylate, with mass ratios of 2%, 5%, 10%, and 20%, respectively. The thickness of each thin film is approximately 20 nm.

The structure of dimethyl 1,3,5,7-cyclooctatetraene-1,2-dicarboxylate (hereinafter referred to as COT1) is:

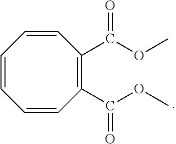 [SMILES: COC(=O)C1=C(C(=O)OC)/C=C\C=C/C=C\1]

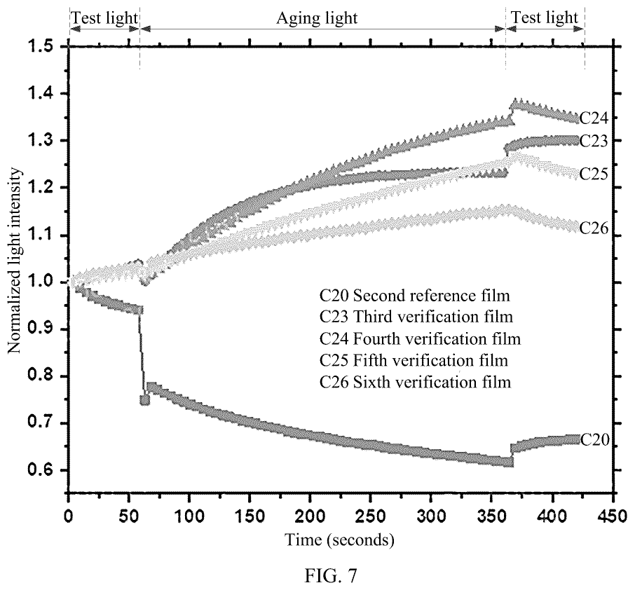

Each film is sequentially irradiated with test light (low intensity), aging light (high intensity), and test light (low intensity), with a wavelength of 405 nanometers. At the same time, the intensity of the light emitted by the hole transport material after excitation is detected, which can reflect the degree of damage to the hole transport material. The stronger the light intensity, the smaller the damage to the hole transport material, and the better the protective effect of the triplet quenching material on the hole transport material. The hole transport material generates photogenerated excitons upon exposure to the light irradiation, and the triplet quenching material can protect the hole transport material by quenching triplet excitons. The verification test results are shown in FIG. 7.

As shown in FIG. 7, when the triplet quenching material is added to the film, the stability of the film under strong light is significantly improved. This indicates that the triplet quenching material can provide protection for the hole transport material.

In some examples of the present disclosure, a test device (red QLED device) is prepared and tested according to the following method.
Step B1) solution preparation: preparing a PEDOT:PSS solution, preparing a mixed solution of TFB and COT1 (12 mg/mL, chlorobenzene solvent, four different mixed solutions, with a mass ratio of COT1 relative to (COT1+TFB) in different mixed solutions is varied at 0%, 5%, 10%, and 20%), and preparing a solution of ZnO nanoparticles (in isopropanol solvent).
Step B2) substrate preparation: cleaning an ITO patterned substrate using water ultrasonic cleaning for 600 seconds and isopropanol ultrasonic cleaning for 300 seconds, and performing UV Ozone (Ultraviolet-Ozone) treatment for 15 minutes.
Step B3) spin coating hole injection layer: spin coating a PEDOT:PSS hole injection layer at 3000 rpm (spin coating speed) for 1 minute.
Step B4) transferring to an inert environment: thoroughly purging the glovebox to ensure low oxygen and water concentration, and transferring the device to an inert environment.
Step B5) spin coating hole transport layer: spin coating the prepared TFB:COT1 mixed solution at 2000 rpm (spin coating speed) for 1 minute, and annealing at 120° C. for 10 minutes.
Step B6) spin coating quantum dot luminescent layer: spin coating using a solution with a concentration of 20 mg/ml, at 2000 rpm (spin coating speed), for 1 minute, and annealing at 100° C. for 10 minutes.
Step B7) spin coating ZnO nanoparticle material: spin coating at 2000 rpm (spin coating speed) for 1 minute, and annealing at 100° C. for 10 minutes.
Step B8) vacuum thermal evaporating A1 to a thickness of approximately 100 nm as the top electrode.
Step B9) using glass plates and epoxy resin for packaging and testing.

In this embodiment, nominally identical test devices D, E, F, and G are prepared. The only difference between test devices D, E, F, and G is the mass ratio (referred to as doping ratio, for convenience of describing embodiments of the present disclosure) of COT1 relative to the total mass of COT1 and TFB in the hole transport layer, which is 0%, 5%, 10%, and 20%, respectively.

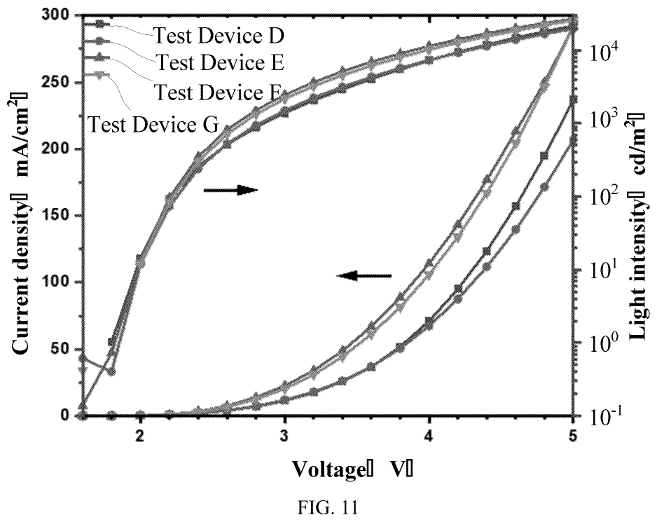

FIG. 11 shows current vs. voltage curves and luminance vs. voltage curves of Test Device D, Test Device E, Test Device F, and Test Device G. As shown in FIG. 11, the current and the luminance of Test Device E are close to those of Test Device D, while the current and the luminance of Test Device F and Test Device G are both greater than those of Test Device D.

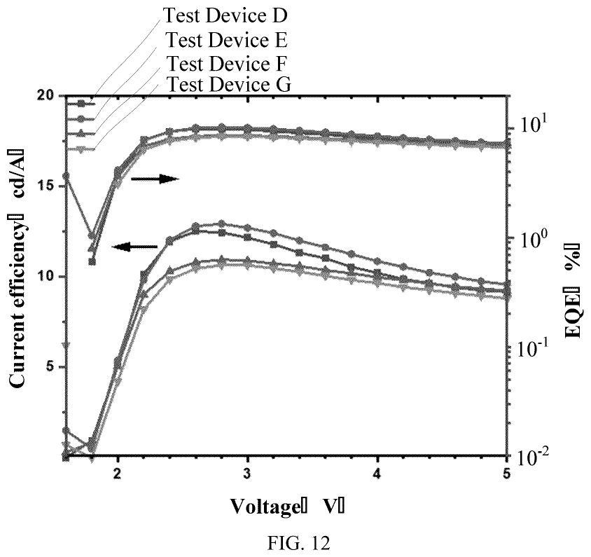

FIG. 12 shows current efficiency vs. voltage curves and external quantum efficiency (EQE) vs. voltage curves of Test Device D, Test Device E, Test Device F, and Test Device G. As shown in FIG. 12, the efficiency of Test Device E is slightly higher than that of Test Device D, while the efficiencies of Test Device F and Test Device G are slightly lower than that of Test Device D.

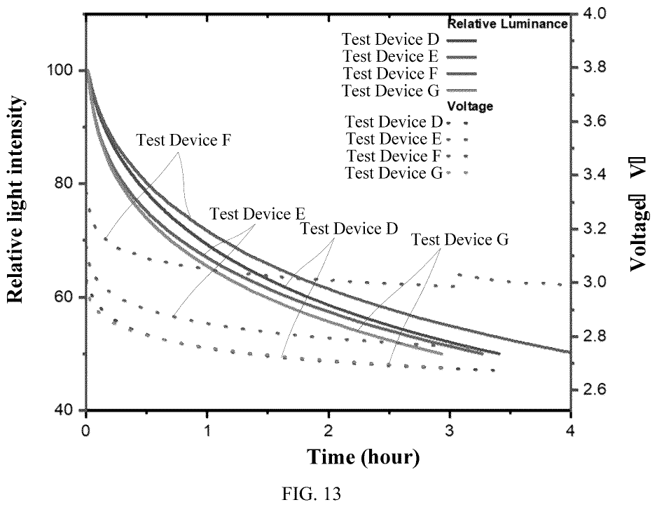

FIG. 13 shows life test results and voltage test results of Test Device D, Test Device E, Test Device F, and Test Device G. In this test, all four devices are operated at a high luminance, and the changes in luminance are detected after reaching the maximum luminance, to determine the degree of the luminance attenuation. In this test, it can be found that the lifetime of Test Device E is higher than that of Test Device D, while the lifetimes of Test Device F and Test Device G are lower than that of Test Device D.

It can be understood that although COT1 is a solid at room temperature, its low boiling point makes it prone to instability issues, resulting in an insufficient film-forming stability when the COT1 and the hole transport materials form the film together. Therefore, the COT compounds can be modified to improve their stability, such as obtaining COT derivative materials with higher boiling points, which can be more effectively used in combination with hole transport materials.

In the following embodiments, the structure, the material, and the preparation method of the thin-film light-emitting device in embodiments of the present disclosure are illustrated.

### Embodiment 1

The thin-film light-emitting device includes an anode, a hole injection layer, a hole transport layer, a quantum dot luminescent layer, an electron transport layer, and a cathode arranged in sequence. In some embodiments, the material of the anode is ITO, the material of the hole transport layer is PEDOT:PSS, the material of the hole transport layer is a mixture of TFB and UV-1084, the material of the electron transport layer is zinc oxide, and the material of the cathode is aluminum.

The following method can be used to prepare the thin-film light-emitting device.
1) Dissolving TFB and UV-1084 in the chlorobenzene to obtain a precursor solution for the hole transport layer. The total mass concentration of TFB and UV-1084 in the precursor solution is 12 mg/mL. The mass ratio of UV-1084 in the film-forming material (UV-1084+TFB) is 1%.
2) Performing the Ultraviolet-Ozone treatment on a patterned ITO substrate (ITO layer+glass layer).
3) Spin coating the PEDOT:PSS at 3000 rpm for 1 minute, followed by annealing at 150° C. in air for 30 minutes to form the hole injection layer.
4) Transferring the device to an inert environment and spin coating the precursor solution for the hole transport layer at 2000 rpm for 1 minute, followed by annealing at 120° C. for 10 minutes to form the hole transport layer.
5) Spin coating a quantum dot solution, with a quantum dot concentration of 20 mg/mL, at 2000 rpm for 1 minute, followed by annealing at 100° C. for 10 minutes to form the quantum dot luminescent layer.
6) Spin coating a zinc oxide precursor solution at 2000 rpm for 1 minute, followed by annealing at 100° C. for 10 minutes to obtain the electron transport layer.
7) Performing the evaporation deposition on the cathode, with a material of aluminum, to a thickness of 100 nm.

### Embodiment 2

The thin-film light-emitting device includes an anode, a hole injection layer, a hole transport layer, a quantum dot luminescent layer, an electron transport layer, and a cathode arranged in sequence. In some embodiments, the material of the anode is ITO, the material of the hole transport layer is PEDOT:PSS, the material of the electron transport layer is zinc oxide, the material of the cathode is aluminum, and the material of the hole transport layer is the following multifunctional polymer:

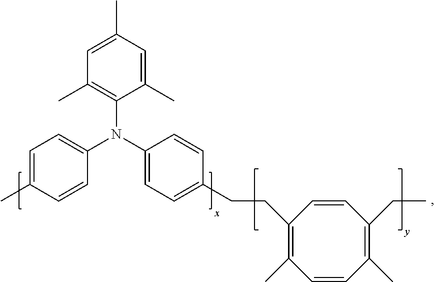

where x represents the number of TFB monomer repeat units, x being equal to 200, and Y represents the number of cyclooctene derivative monomer repeat units, y being equal to 2.

In some embodiments, the hole transport material and the triplet quenching material crosslink to form a multifunctional polymer, such that the multifunctional polymer has segments for hole transport and segments for quenching triplet states.

In some embodiments, the thin-film light-emitting device can be prepared by referring to the preparation method of Embodiment 1, with the only difference being that the multifunctional polymer of this embodiment is used as the film-forming material when preparing the precursor solution for the hole transport layer. The mass concentration of the film-forming material in the precursor solution for the hole transport layer is 12 mg/mL.

### Embodiment 3

The thin-film light-emitting device includes an anode, a hole transport layer, a quantum dot luminescent layer, an electron transport layer, and a cathode stacked in sequence. In some embodiments, the material of the anode is molybdenum oxide/silver, the material of the hole transport layer is CBP doped with anthracene, the material of the electron transport layer is zinc oxide, and the material of the cathode is ITO.

The structure of CBP is as follows:

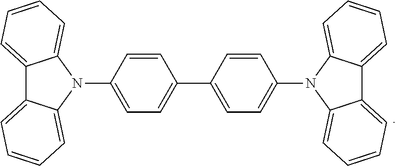 [SMILES: c1ccc2c(c1)c1ccccc1n2-c1ccc(-c2ccc(-n3c4ccccc4c4ccccc43)cc2)cc1]

The following method can be used to prepare the thin-film light-emitting device.
1) Performing the Ultraviolet-Ozone treatment on a patterned ITO substrate (ITO layer+glass layer).
2) Spin coating a zinc oxide precursor solution at 2000 rpm for 1 minute, followed by annealing at 100° C. for 10 minutes to obtain the electron transport layer.
3) Spin coating a quantum dot solution, with a quantum dot concentration of 20 mg/mL, at 2000 rpm for 1 minute, followed by annealing at 100° C. for 10 minutes to form the quantum dot luminescent layer.
4) Forming a stable hole transport layer through a co-evaporation process, with CBP (evaporation rate of 1 nm/min) used for source 1 and anthracene (evaporation rate of 0.1 nm/min) used for source 2, with a co-evaporation of 50 nm.
5) Performing the evaporation deposition on the cathode, with a material of molybdenum/silver oxide, to a thickness of 3 nm/100 nm.

### Embodiment 4

The thin-film light-emitting device includes an anode, a hole transport layer, a quantum dot luminescent layer, an electron transport layer, and a cathode stacked in sequence. In some embodiments, the material of the anode is molybdenum oxide/silver, the material of the hole transport layer is a mixture of CPB and COT-functionalized CPB, the material of the electron transport layer is zinc oxide, and the material of the cathode is ITO.

The structure of the COT-functionalized CPB (multifunctional material) is as follows:

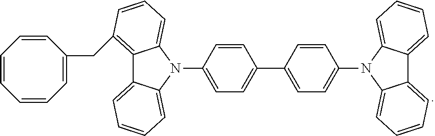 [SMILES: C1=C\C=C/C(Cc2cccc3c2c2ccccc2n3-c2ccc(-c3ccc(-n4c5ccccc5c5ccccc54)cc3)cc2)=C\C=C/1]

The following method can be used to prepare the thin-film light-emitting device.
1) Performing the Ultraviolet-Ozone treatment on a patterned ITO substrate (ITO layer+glass layer).
2) Spin coating a zinc oxide precursor solution at 2000 rpm for 1 minute, followed by annealing at 100° C. for 10 minutes to obtain the electron transport layer.
3) Spin coating a quantum dot solution, with a quantum dot concentration of 20 mg/mL, at 2000 rpm for 1 minute, followed by annealing at 100° C. for 10 minutes to form the quantum dot luminescent layer.
4) Forming a stable hole transport layer through a co-evaporation process, using a mixture (1:1) of CBP and COT-functionalized CPB as a source material, with an evaporation deposition rate of 1 nm/min and a co-evaporation of 50 nm.
5) Performing the evaporation deposition on the cathode, with a material of molybdenum/silver oxide, to a thickness of 3 nm/100 nm.

Embodiments of the present disclosure also provide a display panel include any of the thin-film light-emitting devices described in the above embodiments. The display panel can be a smartphone screen, a smartwatch screen, or other types of display screens. Due to the fact that the display panel has any of the thin-film light-emitting devices described in the above embodiments, it has the same beneficial effects, which will not be repeated in the present disclosure.

After considering the specification and practicing of the invention disclosed herein, those skilled in the art will easily come up with other implementation solutions of the present disclosure. The present disclosure aims to cover any variations, uses, or adaptive changes of the present disclosure, which follow the general principles of the present disclosure and include common knowledge or commonly used technical means in the art that are not disclosed in the present disclosure. The specification and embodiments are only considered exemplary, and the true scope and spirit of the present disclosure are defined by appended claims.

1. A thin-film light-emitting device comprising an anode, a hole transport layer, a light-emitting layer, and a cathode stacked in sequence;
wherein the hole transport layer comprises a hole transport material and a triplet quenching material, and the triplet quenching material is capable of quenching at least a portion of triplet excitons in the hole transport material; and
wherein the triplet quenching material comprises a linking group and at least one quenching group attached to the linking group, and a structure of the quenching group is selected from structures: 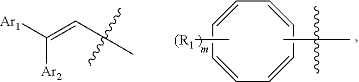
where Ar₁ and Ar₂ are independently selected from substituted or unsubstituted aryl with 6-30 carbon atoms, and substituted or unsubstituted heteroaryl with 4-30 carbon atoms;
R₁ is selected from deuterium, alkyloxycarbonyl with 1-18 carbon atoms, alkylcarbonyl with 1-18 carbon atoms, alkoxyl with 1-18 carbon atoms, alkyl with 1-18 carbon atoms, cycloalkoxycarbonyl with 5-10 carbon atoms, cycloalkylcarbonyl with 5-10 carbon atoms, cycloalkoxyl with 5-10 carbon atoms, cycloalkyl with 5-10 carbon atoms, substituted or unsubstituted aryl with 6-18 carbon atoms, and substituted or unsubstituted heteroaryl with 4-18 carbon atoms; and
m is a positive integer selected from 0-7.

2. The thin-film light-emitting device according to claim 1, wherein a number of the quenching group of the triplet quenching material is 2-4.

3. The thin-film light-emitting device according to claim 1, wherein the quenching group of the triplet quenching material is selected from 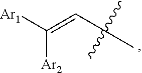
the linking group of the triplet quenching material has an aromatic structure, and the quenching group is directly attached to the aromatic structure.

4. The thin-film light-emitting device according to claim 3, wherein Ar₁ and Ar₂ are independently selected from substituted or unsubstituted phenyl, substituted or unsubstituted naphthyl, and substituted or unsubstituted biphenyl;
in the case that Ar₁ or Ar₂ has a substituent, any substituent is selected from deuterium, methyl, ethyl, and isopropyl.

5. The thin-film light-emitting device according to claim 3, wherein the linking group is selected from substituted or unsubstituted biphenyl, substituted or unsubstituted spirofluorenyl, substituted or unsubstituted triphenyl, substituted or unsubstituted naphthyl, substituted or unsubstituted anthracene, substituted or unsubstituted phenanthrene, and substituted or unsubstituted phenyl;
in the case that the linking group has a substituent, any substituent is independently selected from deuterium, methyl, ethyl, and isopropyl.

6. The thin-film light-emitting device according to claim 3, wherein the triplet quenching material is selected from 4,4′-Bis(2,2-diphenylethenyl)-1,1′-biphenyl and 2,2,7,7′-Tetrakis(2,2-diphenylethenyl)-9,9′-spirobifluorene.

7. The thin-film light-emitting device according to claim 1, wherein the quenching group of the triplet quenching material is selected from 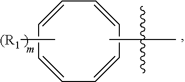
and a molecular weight of the triplet quenching material is between 600 and 1200.

8. The thin-film light-emitting device according to claim 7, wherein the linking group has an organic semiconductor structure with a hole transport property, or the linking group is a flexible linking group with at least two flexible arms, and any one of the flexible arms is attached to one of the at least one quenching group.

9. The thin-film light-emitting device according to claim 1, wherein a Highest Occupied Molecular Orbital (HOMO) energy level of the triplet quenching material is not higher than the HOMO energy level of the hole transport material.

10. The thin-film light-emitting device according to claim 1, wherein a difference between a Lowest Unoccupied Molecular Orbital (LUMO) energy level of the triplet quenching material and the LUMO energy level of the hole transport material is not lower than −1 eV.

11. The thin-film light-emitting device according to claim 10, wherein the LUMO energy level of the triplet quenching material is not lower than the LUMO energy level of the hole transport material.

12. The thin-film light-emitting device according to claim 1, wherein a hole mobility of the triplet quenching material is less than the hole mobility of the hole transport material.

13. The thin-film light-emitting device according to claim 1, wherein a triplet energy level of the triplet quenching material is lower than the triplet energy level of the hole transport material.

14. The thin-film light-emitting device according to claim 1, wherein a singlet energy level of the triplet quenching material is higher than the singlet energy level of the hole transport material.

15. The thin-film light-emitting device according to claim 1, wherein a mass ratio of the triplet quenching material in the hole transport layer is between 0.0001% and 90%.

16. The thin-film light-emitting device according to claim 15, wherein the mass ratio of the triplet quenching material in the hole transport layer is between 1% and 30%.

17. The thin-film light-emitting device according to claim 15, wherein the mass ratio of the triplet quenching material in the hole transport layer is between 2% and 10%.

18. The thin-film light-emitting device according to claim 1, wherein the hole transport material is an organic semiconductor material, and the light-emitting layer is a quantum dot luminescent layer.

19. The thin-film light-emitting device according to claim 1, wherein the thin-film light-emitting device is a blue thin-film light-emitting device.

20. A display panel comprising a thin-film light-emitting device, wherein the thin-film light-emitting device comprises an anode, a hole transport layer, a light-emitting layer, and a cathode stacked in sequence;
wherein the hole transport layer comprises a hole transport material and a triplet quenching material, and the triplet quenching material is capable of quenching at least a portion of triplet excitons in the hole transport material; and
wherein the triplet quenching material comprises a linking group and at least one quenching group attached to the linking group, and a structure of the quenching group is selected from structures: 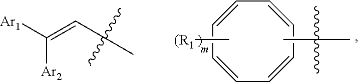
where Ar₁ and Ar₂ are independently selected from substituted or unsubstituted aryl with 6-30 carbon atoms, and substituted or unsubstituted heteroaryl with 4-30 carbon atoms:
R₁ is selected from deuterium, alkyloxycarbonyl with 1-18 carbon atoms, alkylcarbonyl with 1-18 carbon atoms, alkoxyl with 1-18 carbon atoms, alkyl with 1-18 carbon atoms, cycloalkoxycarbonyl with 5-10 carbon atoms, cycloalkylcarbonyl with 5-10 carbon atoms, cycloalkoxyl with 5-10 carbon atoms, cycloalkyl with 5-10 carbon atoms, substituted or unsubstituted aryl with 6-18 carbon atoms, and substituted or unsubstituted heteroaryl with 4-18 carbon atoms; and
m is a positive integer selected from 0-7.
